(19) United States
(12) Patent Application Publication
(10) Pub. No.: US 2009/0045444 A1
(43) Pub. Date: Feb. 19, 2009

(54) INTEGRATED DEVICE AND CIRCUIT SYSTEM

(76) Inventor: Holger Huebner, Baldham (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/838,162

(22) Filed: Aug. 13, 2007

(51) Int. Cl. H01L 27/108; H01L 21/00; H01L 23/02

(52) U.S. Cl. 257/296; 257/686; 438/109; 257/E23.18; 257/E27.084

(57) ABSTRACT

An integrated circuit, comprising a substrate stack, comprising a first substrate and a second substrate, the first substrate comprising a first contact field on a side face of the substrate stack and the second substrate comprising a second contact field on the side face; a side substrate, comprising a first contact pad and a second contact pad, the first contact pad being coupled to the second contact pad; first connection, connecting the first contact field and the first contact pad; and a second connection, connecting the second contact field and the second contact pad.

### BACKGROUND OF THE INVENTION

1. Field of the Invention

The invention generally relates to integrated circuits and, more particularly, integrated circuits in a stacked arrangement.

2. Description of the Related Art

Modern electronic devices typically include several integrated circuits which perform functions for the electronic devices. The integrated circuits may include one or more processors, volatile memory devices, non-volatile memory devices, and/or memory controllers. In some cases, to reduce the cost of an electronic device and simplify development and manufacturing of the electronic device, one or more of the integrated circuits within the electronic device may be placed in a multi-chip package. For example, where a processor in an electronic device accesses one or more memory circuits using a memory controller, the one or more memory circuits and/or the memory controller may be placed in a multi-chip package (MCP).

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A through 1D show a schematic view of a substrate stack in various stages during manufacturing, according to an embodiment of the present invention;

FIGS. 2A through 2D show a schematic view of a substrate stack in various stages during manufacturing, according to an embodiment of the present invention;

FIGS. 3A through 3E show schematic views of a substrate stack, according to embodiments of the present invention;

FIGS. 4A and 4B show schematic views of a substrate stack in conjunction with a carrier substrate, according to an embodiment of the present invention;

FIGS. 5A and 5B show schematic views of a substrate stack in conjunction with a circuit board, according to an embodiment of the present invention;

FIGS. 6A and 6B show schematic views of a substrate stack in conjunction with a circuit board, according to an embodiment of the present invention;

FIGS. 7A and 7B show schematic views of a substrate stack in conjunction with a circuit board, according to an embodiment of the present invention;

FIGS. 8A through 8C show schematic views of an integrated device in conjunction with a circuit board, according to embodiments of the present invention;

FIGS. 9A through 9D show schematic views of integrated devices in conjunction with a circuit board, according to embodiments of the present invention;

FIGS. 10A and 10B show schematic views of an integrated device according to embodiments of the present invention; and

FIGS. 11A and 11B show schematic top views of a circuit board in conjunction with an integrated device, according to an embodiment of the present invention.

### DETAILED DESCRIPTION OF THE PREFERRED EMBODIMENT

Various embodiments of the present invention may provide particular advantages for an improved integrated device, an improved memory device, an improved circuit system, and an improved method of fabricating an integrated device.

For one embodiment of the present invention an integrated circuit is provided, the integrated circuit including a substrate stack. The substrate stack includes a first substrate and a second substrate, the first substrate comprising a first contact field on a side face of the substrate stack and the second substrate comprising a second contact field on the side face. The substrate stack further includes a side substrate, comprising a first contact pad and a second contact pad, the first contact pad being coupled to the second contact pad; a first connection, connecting the first contact field and the first contact pad; and a second connection, connecting the second contact field and the second contact pad.

For one embodiment of the present invention a memory device is provided. The memory device includes a chip stack, comprising a first memory chip and a second memory chip, the first memory chip comprising a first signal line and the second memory chip comprising a second signal line, the first signal line extending toward a side face of the chip stack in an area of a first contact field, and the second signal line extending toward the side face of the chip stack in an area of a second contact field. The chip stack further includes a side substrate, comprising a first contact pad and a second contact pad, the first contact pad being coupled to the second contact pad; a first connection, connecting the first signal line in the area of the first contact field to the first contact pad; and a second connection, connecting the second signal line in the area of the second contact field to the second contact pad.

For one embodiment of the present invention a circuit system is provided in which the circuit system comprises a substrate stack having a signal line extending toward a side face of the substrate stack in an area of a contact field. The circuit system further included a side substrate having a first contact pad and a second contact pad, the first contact pad being coupled to the second contact pad; a first connection, connecting the first contact pad to the signal line of the substrate stack in the area of the contact field; a circuit board, the circuit board comprising a third contact pad; and a second connection, connecting the second contact pad to the third contact pad.

For one embodiment of the present invention a circuit system is provided. The circuit system comprises a substrate stack, with a signal line extending toward a side face of the substrate stack in an area of a contact field. The system further includes a circuit board having a contact pad, and a connection connecting the contact pad to the signal line of the substrate stack in the area of the contact field.

For one embodiment of the present invention a method of fabricating an integrated device is provided. The method includes providing of a substrate stack comprising a substrate with a signal line, the signal line extending toward a side face of the substrate stack; a flattening of the side face of the substrate stack, until a cross section of the signal line provides a contact field; a providing of a side substrate comprising a contact pad; an arranging of the substrate stack and the side substrate, such that the contact field faces the contact pad; and a providing of a connection of the contact field to the contact pad.

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit equally effective embodiments.

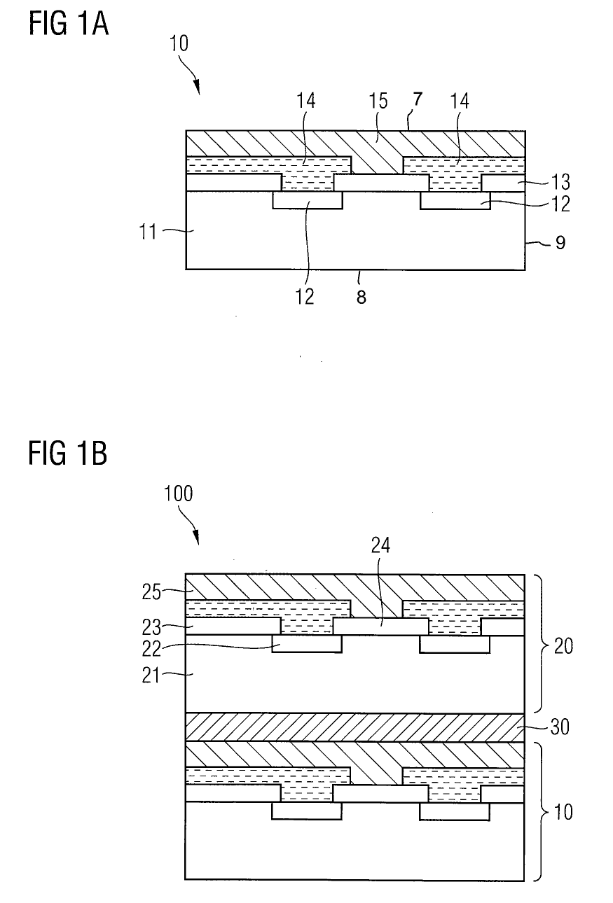

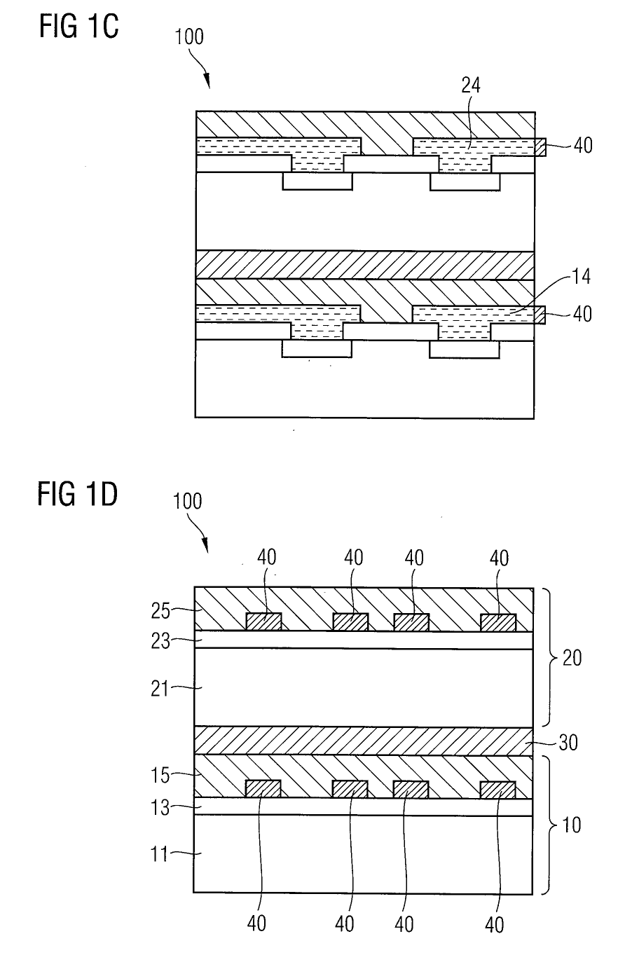

FIGS. 1A through 1D show schematic views of a substrate stack in various stages during manufacturing, according to an embodiment of the present invention. FIG. 1A shows a first substrate 10, which comprises a base substrate 11, contact pads 12, an insulating layer 13 (also referred to herein as the isolation layer 13), signal lines 14, and a passivating layer 15. A substrate may also be denoted as a chip or as a die. For example, a memory chip may comprise a substrate with a respective memory circuit; or a processor (or CPU) chip may comprise a substrate with a respective processor circuit. Hence, a substrate stack, a chip stack, or a die stack may comprise two or more stacked substrates, chips, or dies, depending on the respective denotation.

The base substrate 11 may comprise a semiconductor substrate, such as a silicon substrate. The base substrate 11 may further comprise functional elements, such as capacitors, resistors, transistors, diodes, driver circuits, conductors, signal lines, light sensors, light emitting diodes, semiconductor lasers, dielectric elements, programmable resistance elements, fuses, insulators, and/or integrated circuits, as they are known from integrated device manufacturing.

The contact pads 12 may allow for a connection to said functional entities of the base substrate 11, and may arranged as center pads. The insulation layer 13 may electrically isolate the signal lines 14 from the base substrate 11 or functional entities thereof or may also electrically isolate one signal line 14 from another signal line 14. The signal lines 14 may comprise copper, tin, bismuth, lead, silver, gold, titan, tungsten, and/or aluminum. Furthermore, the signal lines 14 may be part of a redistribution layer. The isolation layer 13 may comprise openings in an area of the contact pads 12, in order to allow for a connection of the contact pads 12 by means of the signal lines 14. The passivating layer 15 may be arranged over at least a portion of the signal lines 14 and may provide insulation of the signal lines 14 and/or may provide protection of the substrate 10 relative to an environment. The passivating layer 15 may further provide a smooth surface of the first substrate 10. The insulating layer 13 and/or the passivating layer 15 may comprise an oxide, silica, spin-on-glass, oxynitride, silicon-oxynitride, and/or polyimide.

In the arrangement shown in FIG. 1A, the substrate 10 defines a top face 7, a bottom face 8 and one or more side faces 9. According to this embodiment of the present invention, at least one signal line 14 extends toward a side face of the substrate 10. A side face 9 of the substrate 10 may in this context be defined as a face being perpendicular to the top face 7 or the bottom face 8 of the substrate 10. In general, the top face 7 and the bottom face 8 are of equal area and are arranged on opposite ends of the substrate 10 and are parallel to one another. The side face 9, usually possessing a smaller area than the top face and the bottom face, may be arranged in a rim area of the substrate 10.

FIG. 1B shows a schematic view of a substrate stack 100, comprising the first substrate 10, an intermediate layer 30, and a second substrate 20. The second substrate 20 may be of the same type as the first substrate 10 or may also comprise another circuitry, as compared to the first substrate 10. The second substrate 20 may again comprise a base substrate 21, a contact pad 22, an isolation layer 23, a signal line 24, and a passivating layer 25. It is referred here to the description of the base substrate 11, the contact pad 12, the isolation layer 13, the signal line 14, and the passivating layer 15, as they have been described in conjunction with FIG. 1A, since said elements may be identical, similar, or of the same type.

The substrate stack 100 may comprise at least two substrates, for example, the first substrate 10 and the second substrate 20, which are stacked along an axis being perpendicular to the top and bottom face of an individual constituent substrate. It is to be noted, however, that the area of a side face of a substrate stack, such as the substrate stack 100, may exceed the area of a top face or a bottom face of a substrate. A side face of a substrate stack, such as the substrate stack 100, may be defined as a face being perpendicular to a top or a bottom face of a constituent substrate.

The substrates of a substrate stack, such as the first substrate 10 and the second substrate 20 may be held together by the intermediate layer 30. This intermediate layer 30 may comprise an adhesive to allow for a stable and reliable mechanical contact amongst the constituent substrates. Furthermore, the passivating layer 15 may comprise adhesive properties such as to replace the intermediate layer 30, hence, rendering the intermediate layer 30 obsolete in this case.

FIG. 1C shows a schematic side view of the substrate stack 100 with portions 40 of solder material attached. The side face of the substrate stack 100 may have been planarized prior to the application of the portions 40 of solder material. Such a planarization may be conducted in order to open or expose the signal lines 14, 24, in an area of a contact field. Furthermore, such a planarization may be conducted in order to provide a smooth and flat side face of the substrate stack 100. Such a planarization and/or flattening may be effected by means of polishing, chemical mechanical polishing, cleaving, etching, grinding, sawing, machining, and/or chipping.

It may not be necessary to flatten the side face of the substrate stack 100, if a respective signal line, which is to extend toward the side face, such as the signal line 14 and/or the signal line 24, is accessible in the area of a contact field. An accessible signal line is such that it may be contacted by means of attaching a portion 40 of solder material. In the case that a respective signal line is not accessible, the substrate stack 100 may be flattened from the side face, until the respective signal line is exposed and provides a cross-section for electrical connection by means of a portion of solder material 40. An opening, exposing a cross-section of the signal lines 14, 24 may suffice for attaching a portion of solder material 40.

The provision of the portions 40 of solder material may be effected by means of electroless plating, such as by means of providing a solution to the side face of the substrate stack 100. Said solution may comprise a solder material and/or compounds of solder materials. Such materials may include tin, copper, silver, lead, bismuth, tin sulfate, tin chloride, sulfuric acid, urea, colophony, and/or bibenzyl. In this way, the portions 40 of the solder material may be provided on cross-sections of the signal lines 14, 24, on the side face of the substrate stack 100 without the need of lithography, etching, electric currents, and/or structuring. The solder material may be only deposited on the respective cross-sections of the signal lines 14 and signal lines 24. A thickness of the portions 40 of solder material may be self-limited during plating and below 2 microns.

The portions 40 may be provided such that they possess a pearl-, ball, drop-, or mushroom-like shape. Such shapes may provide a curvatured surface, which may support a void free connection once the material of the portions 40 is heated and melted for, e.g., soldering. Nevertheless, the effective footprint of the portions 40 may not exceed the area of a contact field, i.e., a cross section of one of the signal lines 14, 24. In this way, further insulating layers or masks around the contact field may be rendered obsolete, since the restricted size and volume of the portions 40 does not allow the undesired connections of entities and elements in the vicinity of the contact field, such as the base substrates 11, 21.

FIG. 1D shows a schematic view of the side face of the substrate stack 100. The first substrate 10, the second substrate 20, and the intermediate layer 30 are seen as they have been described in conjunction with FIGS. 1A through 1C. As shown here, the portions 40 of a solder material have been provided on the side face of the substrate stack 100. Said portions 40 connect to the respective functional entities of the first substrate 10 and the second substrate 20 by means of the signal lines 14 and signal lines 24.

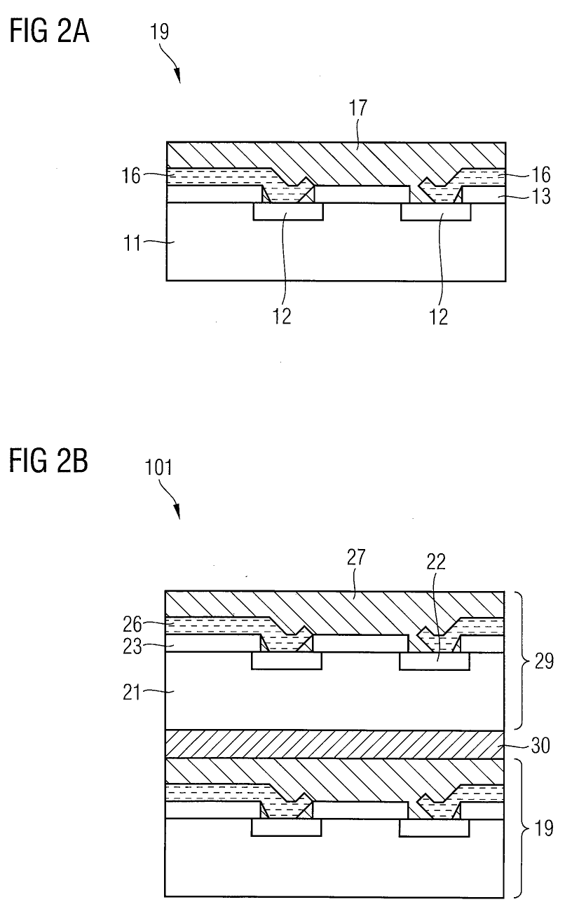

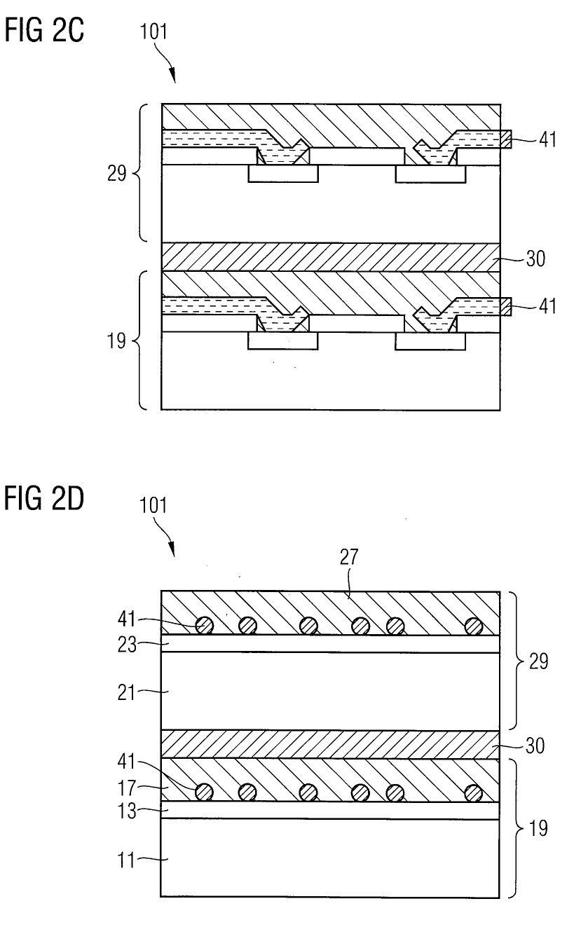

FIGS. 2A through 2D show schematic views of a substrate stack in various stages during manufacturing, according to an embodiment of the present invention. FIG. 2A shows a first substrate 19, comprising the base substrate 11, a contact pad 12, and the isolation layer 13 as they have been described already in conjunction with FIG. 1A.

According to this embodiment, however, the first substrate 19 comprises bond wires 16, which act as signal lines. Said bond wires 16 are attached to the contact pads 12, for example, by means of ball bonding and/or wedge bonding. The wires 16 are then led toward the side face of the first substrate 19. A passivating layer 17 isolates the bond wire 16 and/or provides a sealing of the substrate. The passivating layer 17 may further provide a smooth surface of the first substrate 19. The bond wires 16 may comprise a copper wire, a gold wire and/or an aluminum wire. A diameter of the bond wire 16 may be 30 microns or below, according to one embodiment. The diameter of the bond wire 16 may also be below 25 microns, or below 15 microns, according to other embodiments. The bond wires 16, 26 may possess an oval, a circular, or a rectangular cross-section, leading to respective geometries of the contact fields.

FIG. 2B shows a substrate stack 101, comprising the first substrate 19, the intermediate layer 30, and a second substrate 29. Said second substrate 29 comprises again the base substrate 21, the contact pads 22, and the insulating layer 23, as they have been described already in conjunction with FIG. 1B. The second substrate 29 further comprises bond wires 26 and a passivating layer 27, which may be identical to, similar to, or as the same type as the bond wires 16 and the passivating layer 17 as both have been described in conjunction with FIG. 2A.

FIG. 2C shows a schematic side view of the substrate stack 101 with portions 41 of solder material attached. The side face of the substrate stack 101 may have been planarized as has been described in conjunction with FIG. 1C. It may not be necessary to flatten the side face of the substrate stack 101, if a respective bond wire, which is to extend toward the side face, such as the bond wires 16 and/or the bond wires 26, are accessible in the area of a contact field.

An accessible bond wire is such that it may be contacted by means of attaching a portion 41 of solder material. If a respective signal line is not accessible, the substrate stack 101 may be flattened from the side face, until the respective bond wire is exposed and provides a cross-section for electrical connection by means of a portion of solder material 41. An opening, exposing a cross-section of the bond wires 16, 26, may suffice for attaching a portion of solder material 41 and may expose a bond wire cross-section with an essentially oval, an essentially circular, or an essentially rectangular cross-section, leading to respective geometries of the contact fields. As far as the provision of the portions 41 of solder material is concerned, is referred to the provision of the portions 40, as this has been described in conjunction with FIG. 1C.

FIG. 2D shows a schematic view of the side face of the substrate stack 101. The first substrate 19, the second substrate 29, and the intermediate layer 30 are seen as they have been described in conjunction with FIGS. 2A through 2C. As shown here, the portions 41 of a solder material have been provided on the side face of the substrate stack 101. Said portions 41 connect to the respective functional entities of the first substrate 19 and the second substrate 29 by means of the bond wires 16 and the bond wires 26. The portions 41 of the solder material may as well as the bond wires 16, 26, possess a cross-section with an essentially circular or oval shape.

Prior to the provision of the portions 40 of solder material there may be effected an optional strengthening and/or thickening of the contact fields, i.e., the respective cross-sections of the signal lines 14, 24 and/or bond wires 16, 26, by means of electroless Cu-plating or Au-plating. Furthermore, the side face or a part thereof of a substrate stack may be insulated. In the case of a bulk semiconductor, for example the side face of a silicon base substrate, this may be effected by means of anodic oxidation.

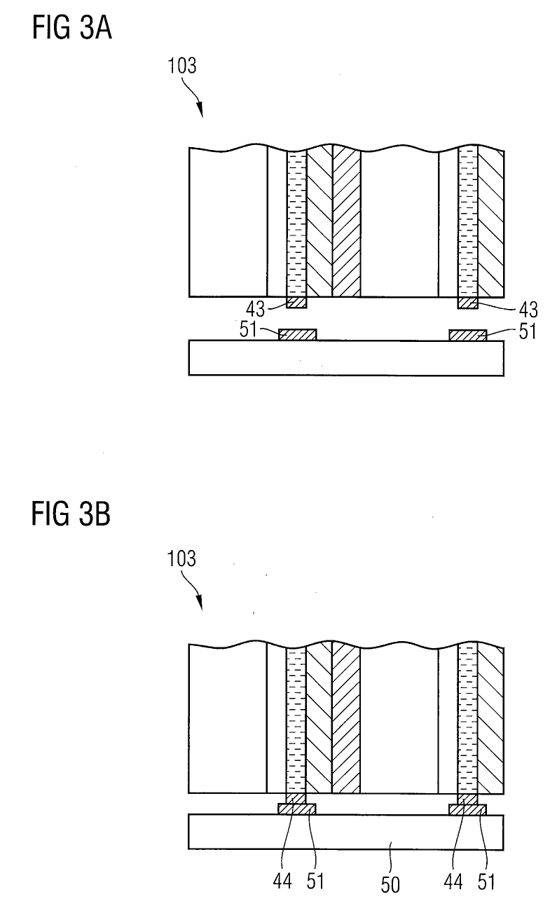

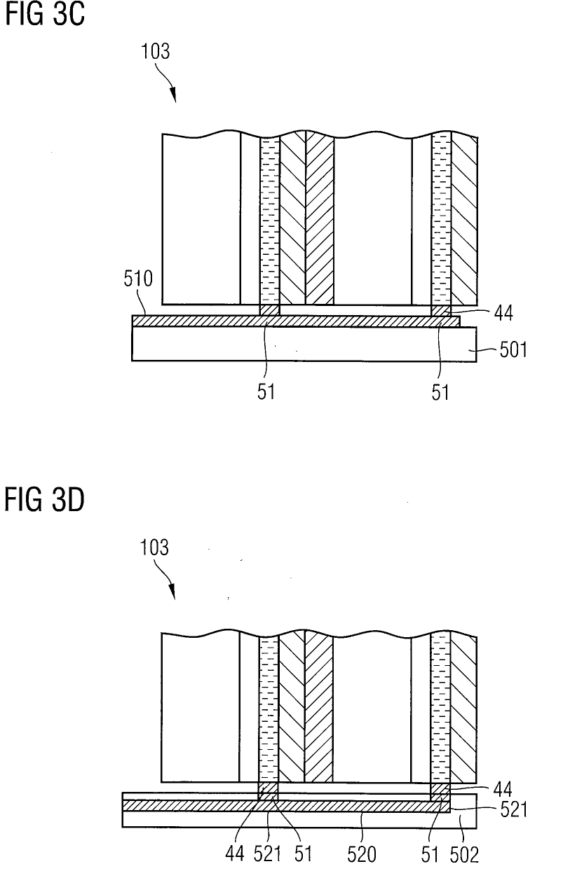

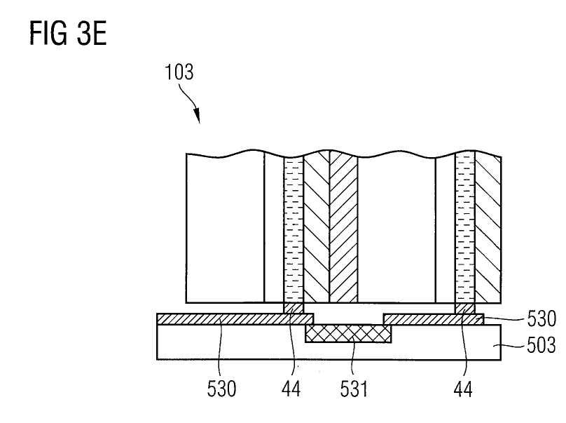

FIG. 3A and FIG. 3B show schematic views of a substrate stack and a side substrate, according to an embodiment of the present invention. A substrate stack 103 may be or comprise a substrate stack according to an embodiment of the present invention, such as the substrate stack 100 or the substrate stack 101 as they have been described in conjunction with FIGS. 1A through 2D. The substrate stack 103 comprises portions 43 of a solder material on a side face of the substrate stack 103. The portions 43 of the solder material provide an electric connection to signal lines, bond wires, and/or functional entities of the substrate stack 103. A side substrate 50 comprises contact pads 51 on a top face of the side substrate 50. As shown in FIG. 3A, the substrate stack 103 is arranged such that the side face of the substrate stack 103 faces the top face of the side substrate 50. The contact pads 51 are arranged on the side substrate 50, such as to match the positions of the portions 43 of the solder material of the substrate stack 103. The side substrate 50 may furthermore comprise more than one substrate itself, such to comprise a further substrate stack.7

In the cause of the subsequent processing, the substrate stack 103 is arranged toward the side substrate 50 such that the portions 43 of the solder material are brought into a vicinity of the contact pads 51. This may also include that the portions 43 of the solder material are brought into contact to the contact pads 51. The arrangement comprising the substrate stack 103 and the side substrate 50 is heated, such that the portions 43 of the solder material form an electric solder connection from the signal lines or bond wires to the respective contact pads 51. It may further suffice, to heat only the portions 43 of the solder material such to form electric solder connections. This may reduce a heating and a thermal budget of the substrate stack 103 and/or the side substrate 50 to minimum.

As shown in FIG. 3B, the signal lines or bond wires of the substrate stack 103 are connected to the side substrate 50 by means of solder connections 44 to the contact pads 51. The solder connections 44 may have been formed by means of infrared soldering, wave soldering, laser soldering, ultrasonic soldering, and/or a heating process. In this way, the substrate stack 103 is connected to the side substrate 50. Furthermore, components or compounds being comprised by the solder material, such as urea, colophony, and/or bibenzyl, may sublimate during the soldering process and may, at least in part, fill a space between the substrate stack 103 and the side substrate 50. In addition, said components or compounds may act as an adhesive, binding the substrate stack 103 to the side substrate 50. The solder connections 44 may furthermore be formed by means of ultrasonic welding, laser-welding, and related processes. Possible alternatives to the solder connections 44 may include a conductive adhesive, anisotropic conductive sheets, or mechanical electrical contacts.

The side substrate 50 may comprise signal lines and/or strip-lines for connecting the contact pads 51 to further contact pads, to bond pads, to balls of a ball grid array, or to contact pins. The side substrate 50 may further comprise an integrated circuit, such as a driver circuit, a logic circuit, an amplifier circuit, a control circuit, a demux-circuit, a modern circuit, and/or a transceiver circuit. As an example, the substrate stack 103 may comprise at least two memory chips, i.e. substrates with an array of memory cells, and the side substrate 50 may comprise the respective control logic for accessing and addressing the respective information being stored in the memory chips.

FIG. 3C shows a schematic view of a substrate stack and a side substrate, according to an embodiment of the present invention. Accordingly, the substrate stack 103 is arranged on a side substrate 501. The side substrate 501 comprises contact pads 51 and a signal line 510 on a top face of the side substrate 501. The signal line 501 couples the contact pads 51 to each other, such that, in turn, the substrates of the substrate stack 103 are coupled to each other. The signal line 510 may extend further on the side substrate 501 in order to allow for a connection to other entities, such as a circuit board, an integrated circuit or an external circuit. A height of the connections 44 may suspend the substrate stack 103 from the side substrate 501, such that undesired electrical connections are suppressed. Nevertheless, a mask and/or a spacer layer may provide additional insulation and/or mechanical fixation.

FIG. 3D shows a schematic view of a substrate stack and a side substrate, according to an embodiment of the present invention. Accordingly, the substrate stack 103 is arranged on a side substrate 502. The side substrate 502 comprises contact pads 51 on a surface of the side substrate 501, such to allow for a connection to the substrate stack 103 by means of the connections 44. The side substrate 502 further comprises a signal line 520 which couples the contact pads 51 to each other, such that, in turn, the substrates of the substrate stack 103 are coupled to each other. The signal line 520 is arranged inside the side substrate 502, such as is a buried signal line, and may be connected to the contact pads 51 by means of vias 521. The signal line 520 may extend further inside the side substrate 502 in order to allow for a connection to other entities. Since insulating material may face the substrate stack 103, further means for insulation and/or the suppression of undesired connections are rendered optional or obsolete. The insulating material may be part of the side substrate and may comprise a semiconductor material, a resin, a polymer, or a ceramic.

FIG. 3E shows a schematic view of a substrate stack and a side substrate, according to an embodiment of the present invention. Accordingly, the substrate stack 103 is arranged on a side substrate 503. The side substrate 503 comprises signal lines 530 which are coupled to the substrate stack 103 by means of the connections 44. The side substrate 503 further comprises a functional unit 531, such as a capacitors, a resistor, a transistor, a diode, a driver circuit, a conductor, a signal line, a light sensor, a light emitting diode, a semiconductor laser, a dielectric element, a programmable resistance element, a fuse, an insulator, and/or an integrated circuit, as they are known from integrated device manufacturing. The signal line 530 couples the substrate stack 103 to a functional unit, such as the functional unit 531, and may couple the substrate stack 103 to a further circuitry by means of the side substrate 503.

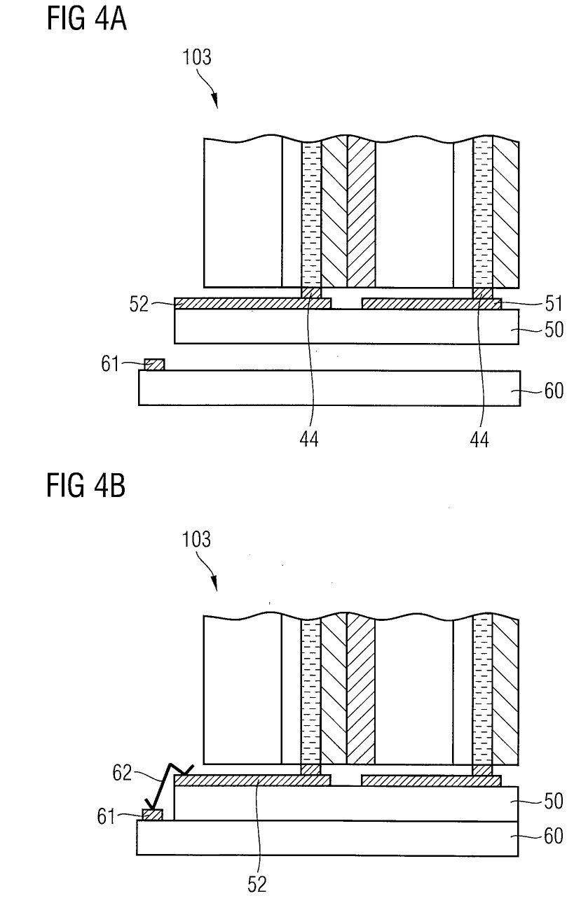

FIGS. 4A and 4B show schematic views of an arrangement comprising a substrate stack, a side substrate, and a carrier substrate, according to an embodiment of the present invention. FIG. 4A shows the substrate stack 103 in conjunction with the side substrate 50, to which the substrate stack 103 is connected by means of solder connections 44. The side substrate 50 comprises signal lines to connect the contact pads 51 to bond pads 52. A carrier substrate 60 comprises a further bond pad 61. The carrier substrate 60 may, in addition, comprise means for contacting and establishing a connection to the bond pads 61, such as further contact pads, contact pins, or a ball grid array. As shown in FIG. 4B, the arrangement comprising the substrate stack 103 and the side substrate 50 is attached to the carrier substrate 60. A bond wire 62 connects the bond pad 61 of the carrier substrate 60 to the bond pad 52 of the side substrate 50.

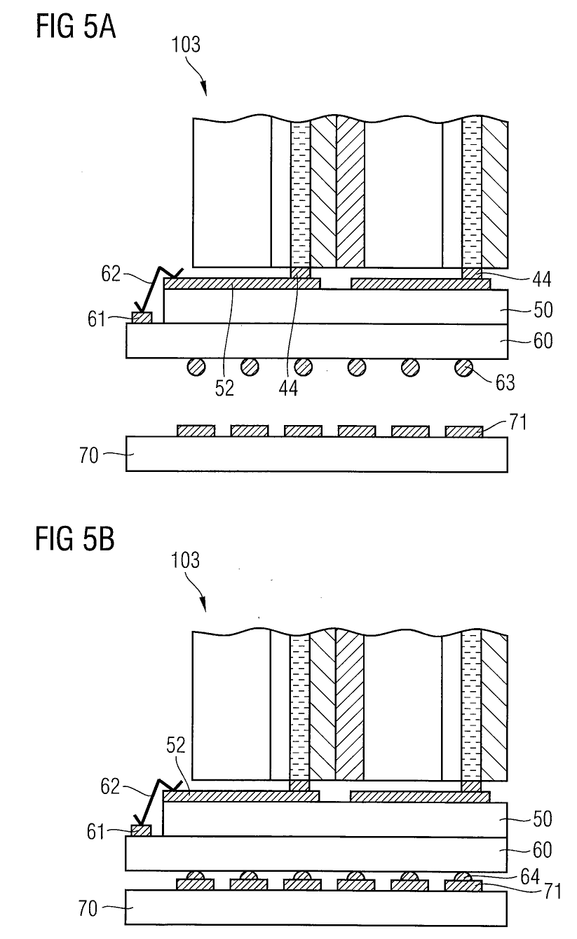

FIGS. 5A and 5B show schematic views of an arrangement comprising a substrate stack, a side substrate, a carrier substrate, and a circuit board, according to an embodiment of the present invention. The substrate stack 103 is connected by means of solder connections 44 to the side substrate 50. The side substrate 50 is connected by means of bond wires 62 to the carrier substrate 60, as has been described in conjunction with FIGS. 4A and 4B. The carrier substrate 60 comprises solder balls 63 on a bottom side of the carrier substrate 60. The solder balls 63 may be part of a ball grid array and may be arranged on respective contact pads. Said contact pads may be connected by means of signal lines to bond pads, such as the bond pad 61, which are, in turn, connected to bond pads by means of bond wires, such as to the bond pad 52 by means of the bond wire 62. A circuit board 70 comprises contact pads 71 on a top surface of the circuit board 70. The positions of the contact pads 71 correspond to the positions of the respective solder balls 63 of the carrier substrate 60.

As shown in FIG. 5B, the arrangement comprising the carrier stack, the side substrate, and the carrier substrate is brought into a vicinity of the circuit board 70, such that the solder balls 63 are arranged in a vicinity of the respective contact pad 71. Said arrangement may be heated, or partially heated, for example, during a wave soldering stage, a reflow soldering stage, an infrared soldering stage, a laser soldering stage, solid interdiffusion, SOLID-processing (SOLID=SOlid Liquid InterDiffusion), and/or an ultrasonic soldering stage, such that the solder balls 63 form solder connections 64 to the contact pads 71.

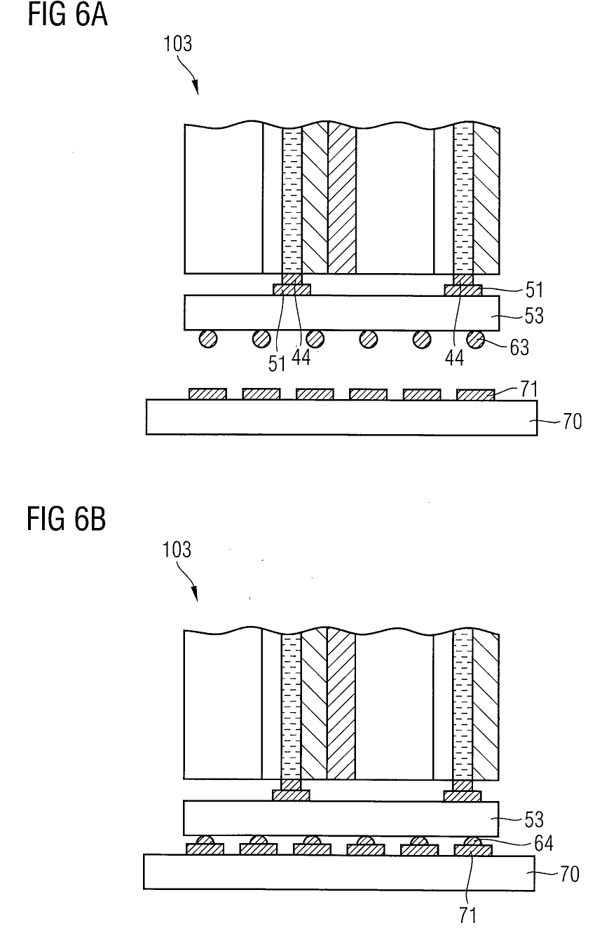

FIGS. 6A and 6B show schematic views of an arrangement comprising a substrate stack, a side substrate, and a circuit board, according to an embodiment of the present invention. FIG. 6A shows the substrate stack 103 connected to a side substrate 53 by means of solder connections 44. Set solder connections 44 connect the substrate stack 103 to contact pads 51, which are arranged on a top surface of the side substrate 53. On a corresponding bottom face of the side substrate 53 there are arranged solder balls 63. The side substrate 53 may comprise means for connecting a contact pad 51 to a corresponding solder ball 63, such as a wire and/or a signal line.

According to this embodiment of the present invention, the side substrate 53 is to be connected to the circuit board 70, which comprises contact pads 71 at respective positions corresponding to the positions of the solder balls 63 of the side substrate 53.

As shown in FIG. 6B, the arrangement comprising the substrate stack, the side substrate, and the carrier substrate is arranged in respect to the circuit board 70, such that the solder balls 63 are arranged in a vicinity of the respective contact pad 71. Said arrangement may be heated, or partially heated, for example, during a wave soldering stage, a reflow soldering stage, an infrared soldering stage, a laser soldering stage, a solid interdiffusion stage, a SOLID-processing stage, and/or an ultrasonic soldering stage, such that the solder balls 63 form solder connections 64 to the contact pads 71.

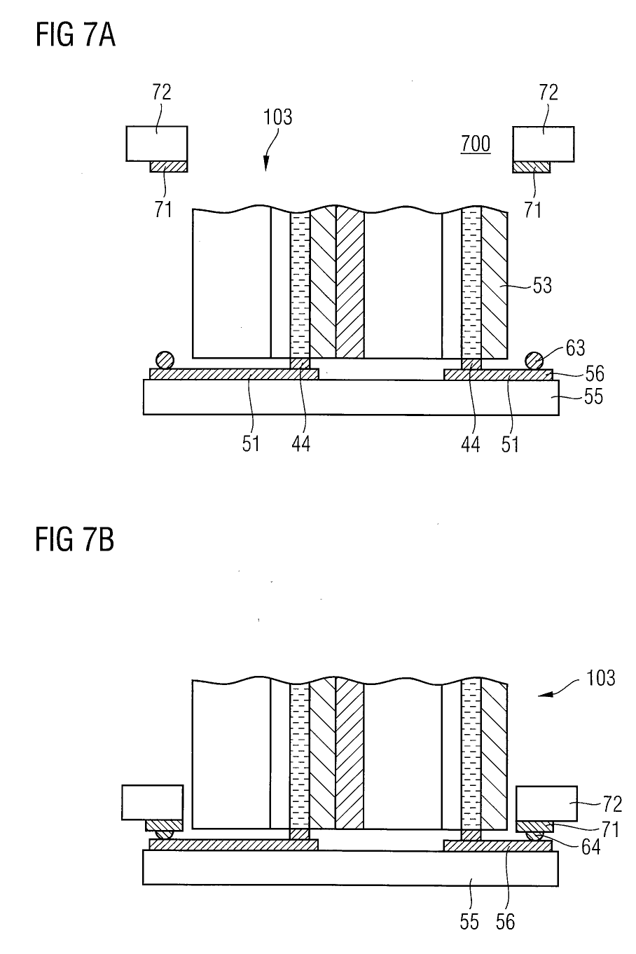

FIGS. 7A and 7B show an arrangement comprising a substrate stack, a side substrate, and a circuit board, according to an embodiment of the present invention. As shown in FIG. 7A, the substrate stack 103 is connected to a side substrate 55 by means of solder connections 44. The solder connections 44 connect the substrate stack 103 to contact pads 51 of the side substrate 55, which are arranged on a top surface of the side substrate 55. The side substrate 55 further comprises contact pads 56 on the top surface of the side substrate 55, in an area which is not covered by the substrate stack 103, i.e. outside the footprint of the substrate stack 103.

The contact pads 56 may be connected to the respective contact pads 51 by means of signal lines. On the contact pads 56 there are arranged solder balls 63. According to this embodiment, a circuit board 72 comprises an opening 700 through which the substrate stack 103 may pass. On a bottom face of the circuit board 72, which is arranged such it faces the top face of the side substrate 55, there are arranged contact pads 71.

As shown in FIG. 7B, the arrangement comprising the substrate stack 103 and the side substrate 55 is arranged in respect to the circuit board 72, such that the substrate stack 103 is inserted into the opening 700 of the circuit board 72 and the solder balls 63 are brought into a vicinity of the circuit board pads 71. In this way, the contact pads 56 of the side substrate 55 are brought into a vicinity of the contact pads 71 of the circuit board 72. The solder balls 63 are soldered such to form a solder connection 64.

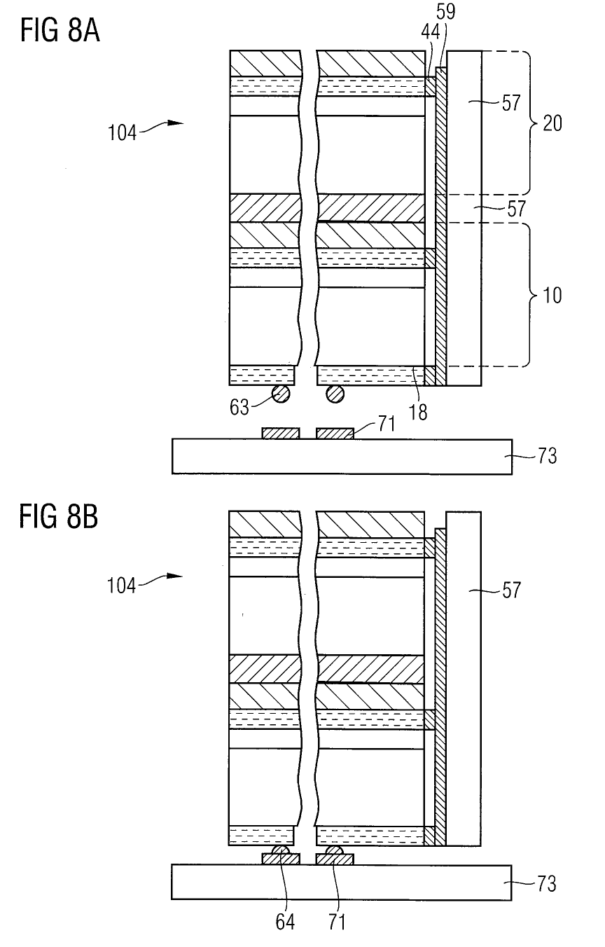

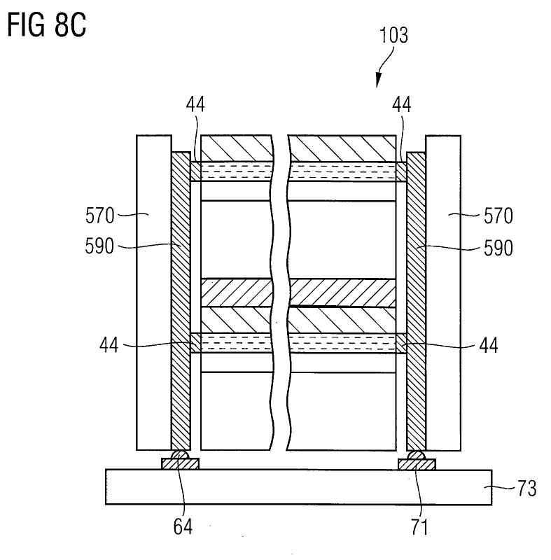

FIGS. 8A and 8B show an arrangement comprising an integrated device and a circuit board, according to an embodiment of the present invention. As shown in FIG. 8A, a substrate stack 104 comprises at least a first substrate 10 and a second substrate 20. According to this embodiment, the substrate stack 104 comprises an additional signal line layer 18, which is arranged on a bottom surface of the bottom substrate, in this case, of the first substrate 10. For the remainder of the substrate stack 104 it is referred to the substrate stack 103 which has been described in conjunction with an embodiment of the present invention.

A side substrate 57 is arranged on a side face of the substrate stack 104 and is connected by means of solder connections 44 to the substrate stack 104. The side substrate 57 comprises signal lines and/or contact pads 59 to connect to the bottom signal line layer 18. On predetermined positions of the signal line layer 18 there are arranged solder balls 63. A circuit board 73 comprises contact pads 71 on a top surface at respective positions in order to connect to the solder balls 63.

As shown in FIG. 8B, the arrangement comprising the substrate stack 104 and the side substrate 57 is soldered onto the circuit board 73 and connected to it by means of solder connections 64. According to an embodiment of the present invention, the substrate stack 104 may be connected to a further side substrate, being arranged on an opposite side face or to another side face of the substrate stack 104. In this way, the connection capacity for inter-connecting the substrates, such as the first substrate 10 and the second substrate 20, to the bottom signal line layer 18 may be increased.

FIG. 8C shows an arrangement comprising an integrated device and a circuit board, according to an embodiment of the present invention. A side substrate 570 is arranged on a side face of the substrate stack 103 and is connected by means of solder connections 44 to the substrate stack 103. The side substrate 570 comprises signal lines and/or contact pads 590 that extend to a bottom side face of the side substrate 570, such to provide there a contact field. The circuit board 73 comprises contact pads 71 on a top surface at respective positions in order to connect to the contact fields of the signal lines 590. On these contact fields of the signal line 590 or on the contact pads 71 of the circuit board 73, there may be arranged solder balls 63, which form the connections 63 when soldered. In such a way, the connection capacity for inter-connecting the substrates, such as the first substrate 10 and the second substrate 20, to an external circuit, e.g. that of the circuit board 73, may be increased.

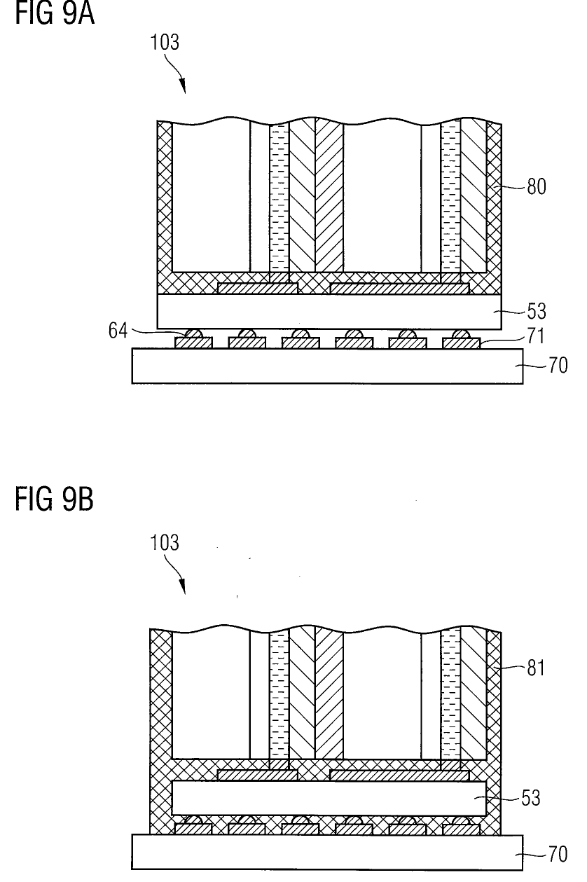

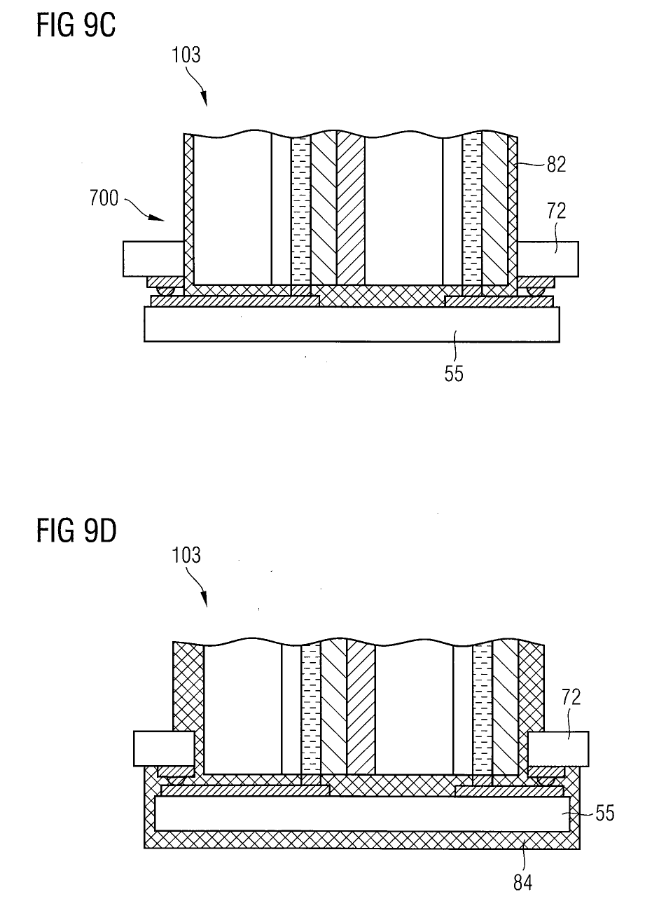

FIGS. 9A through 9D show arrangements comprising an integrated device, a circuit board, and a package, according to embodiments of the present invention. FIG. 9A shows an arrangement comprising an integrated device and a circuit board, according to an embodiment of the present invention. A substrate stack, such as the substrate stack 103 is at least in part surrounded by a package 80. The package 80 may provide mechanical and/or electric protection to the integrated circuits of the substrate stack 103. The substrate stack 103 is connected to a side substrate 53 as has been described in conjunction with an embodiment of the present invention. Furthermore, the side substrate 53 is connected to the circuit board 70 as has been described in conjunction with an embodiment of the present invention. The package 80 may surround the entire substrate stack 103 and may also fill the space between the substrate stack 103 and the side substrate 53. The package 80 may comprise a mold, a resin, a ceramic and/or a polymer material.

FIG. 9B shows an arrangement comprising an integrated device and a circuit board, according to an embodiment of the present invention. As compared to the arrangement which has been described in conjunction with FIG. 9A, according to this embodiment, a package 81 extends to the circuit board 70. Furthermore, the package 81 may fill the space between the side substrate 53 and the circuit board 70. The package 81 may be provided after connecting the substrate stack 103 to the side substrate 53 and after connecting the side substrate 53 to the circuit board 70. This provision may be effected in a liquid state, such as a provision of a liquid resin. The resin may solidify by means of a polymerization, which may be induced by a heating process and/or adding a chemical additive.

FIG. 9C shows an arrangement comprising an integrated device and a circuit board, according to an embodiment of the present invention. A similar arrangement is shown as has been described in conjunction with FIGS. 7A and 7B, comprising the substrate stack 103, the side substrate 55, and the circuit board 72 with an opening 700. According to this embodiment of the present invention, a package 82, at least in part, surrounds the substrate stack 103 and the side substrate 55. It may furthermore fill the space between the substrate stack 103 and the side substrate 55. The package 82 may have been applied prior to the insertion of the substrate stack 103 into the opening 700 of the circuit board 72, or may have been provided after insertion. The package 82 may comprise a cross-section which matches the aperture of the opening 700 of the circuit board 72. In addition to this, the package 82 may comprise features, which may match with corresponding features of the aperture of the opening 700 of the circuit board 72, such that the insertion of the substrate stack 103 may be effected only in an allowed manner and/or orientation. A ready discrete device, such as an integrated circuit, may comprise the substrate stack 103, the side substrate 55, and the package 82.

FIG. 9D shows an arrangement comprising an integrated device and a circuit board, according to an embodiment of the present invention. A similar arrangement is shown as has been described in conjunction with FIG. 9C, comprising the substrate stack 103, the side substrate 55, and the circuit board 72 with an opening 700. According to this embodiment of the present invention, a package 84, at least in part, surrounds the substrate stack 103 and the side substrate 55. It may furthermore fill the space between the substrate stack 103 and the side substrate 55 and or the space between the side substrate 55 and the circuit board 72.

The package 84 may have been in part applied prior to the insertion of the substrate stack 103 into the opening 700 of the circuit board 72, or may have been provided after insertion. Said provision may be effected during two stages, a provision of a first part of the package 84 surrounding a top part of the substrate stack 103, and a second part of the package 84 surrounding a bottom part of the substrate stack 103 and the side substrate 55, the bottom part of the substrate stack being located toward the side substrate 55 as opposed to the top part of the substrate stack 103.

The package 84 may comprise a cross-section which matches the aperture of the opening 700 of the circuit board 72. In addition to this, the package 84 may comprise features, which may match with corresponding features of the aperture of the opening 700 of the circuit board 72, such that the insertion of the substrate stack 103 may be effected only in an allowed manner and/or orientation. A ready discrete device, such as an integrated circuit, may comprise the substrate stack 103, the side substrate 55, and the package 84, or parts thereof.

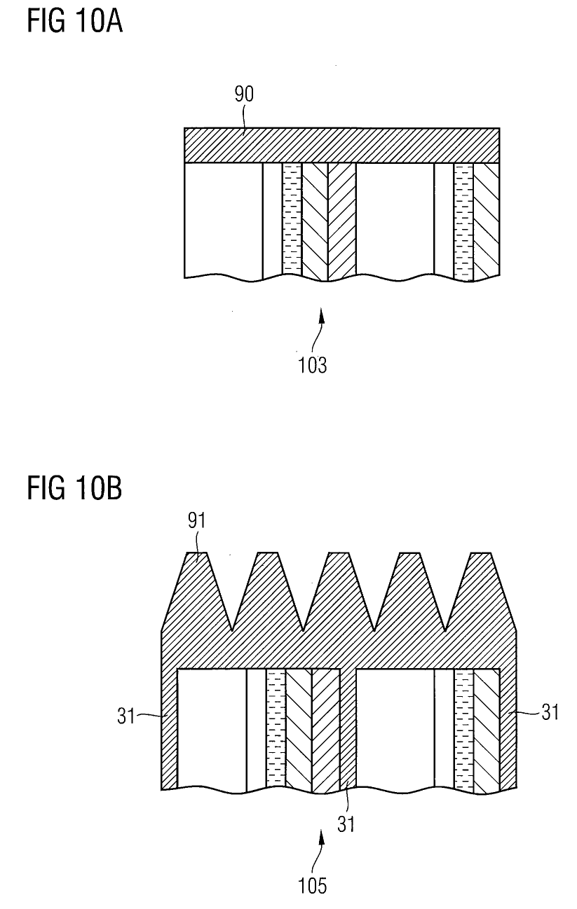

FIG. 10A shows an integrated device according to an embodiment of the present invention. According to this embodiment, the integrated device comprises a heart spreader 90 and the substrate stack 103. The substrate stack 103 is thermally coupled to the heat spreader 90. The heat spreader 90 may be arranged on a side face which is opposite to the side face which comprises the contact fields and on which solder connections are located. Furthermore, the heat spreader 90 may comprise a metallization and or a sheet metal.

FIG. 10B shows an integrated device according to an embodiment of the present invention. According to this embodiment, a substrate stack 105 comprises heat conductive layers 31 which may conduct thermal heat from within the substrate stack 105 to a side face of the substrate stack 105. The heat conductive layers may be or comprise additional signal lines, such as signal lines 14, 24 or bond wires 16, 26. Such signal lines or bond wires may comprise copper, silver, aluminum, and/or gold, which may serve as good thermal conductors. As for the remainder of the substrate stack 105 it is referred to the substrate stack 103 or the substrate stack 104 which have been described in conjunction with an embodiment of the present invention.

On said side face there is arranged a heat spreader 91 which may comprise features or structures in order to increase an effective surface and to ease heat exchange to an environment. The heat spreader 91 may be arranged on a side face of the substrate stack 104 which may be opposite to the side face of the substrate stack 104 which comprises the contact fields. fields and on which solder connections are located.

Both heat spreaders 90 or 91 and the optional heat conductive layers 31 may also serve as electromagnetic screens, since signals within the constituent substrates often are include high-frequency electric signals, which may radiate and may cause interference. Furthermore, both heat spreaders 90 or 91 may be arranged on and/or extend to more than one face of a substrate stack. Such faces include the side faces, the respective top face and bottom face, and the side faces toward which the signal lines extend and/or on which the contact fields are arranged.

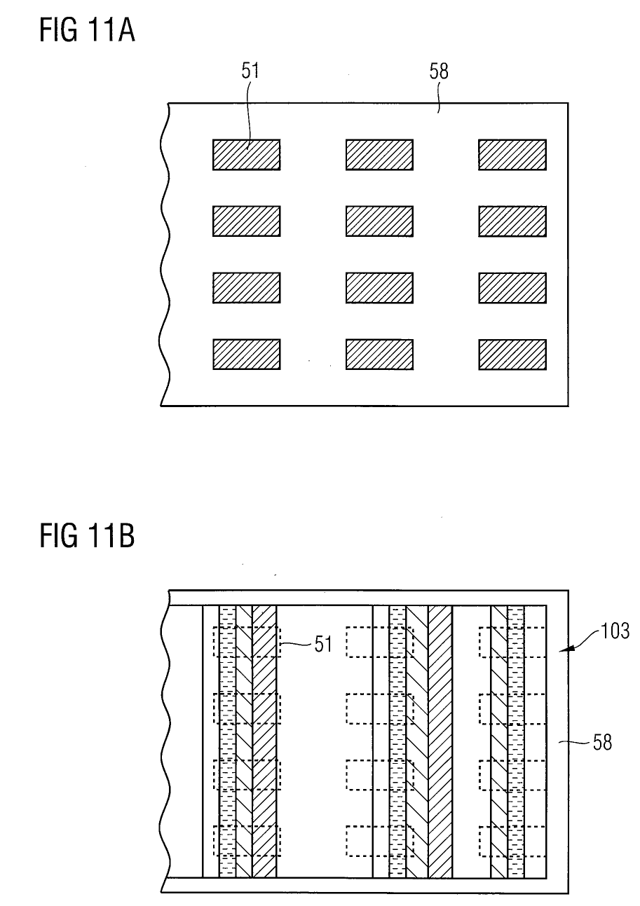

FIGS. 11A and 11B show an arrangement comprising a circuit board and a substrate stack according to an embodiment of the present invention. FIG. 11A shows a schematic top view of a side substrate 58 on which contact pads 51 are arranged. The side substrate 58 may be or comprise the side substrate 50, the side substrate 53, the side substrate 55, and/or the side substrate 57. Furthermore, the side substrate 58 may also be understood as a circuit board, such as the circuit board 70, the circuit board 72, or the circuit board 73, in the case that a substrate stack is to be connected directly to a circuit board. In such a case the contact pads 51 may refer to contact pads, such as the contact pads 71. The arrangement of the contact pads 51 may be in an array, such as to connect to a ball grid array of an integrated device. The arrangement of the contact pads 51 may furthermore comprise more than one array comprising a regular and/or a periodic arrangement of contact pads 51. As shown in FIG. 11B, the substrate stack 103 is arranged onto side substrate 58. The position of the contact pads 51 is indicated by the dashed fields in FIG. 11B.

According to this embodiment of the present invention, the contact pads 51 are shaped such that a misalignment of the substrate stack 103 and/or different height of the constituent substrates of the substrate stack 103 is compensated for. This may be achieved by a rectangular, an oval and/or a shape of the contact pads 51 which provides a larger dimension along the stacking axis of the substrate stack 103 than along a direction which is perpendicular to said axis. Furthermore, it may be effected by a square-like and/or a circular shape, as long as the effective width of the contact pads 51 along the stacking axis suffices for compensation of a respective misalignment and/or a varying height of the constituent substrates of the substrate stack 103.

According to one of the described embodiments of the present invention, the side substrate 50, the side substrate 53, the side substrate 55, the side substrate 57, and/or the side substrate 58 may comprise a circuitry or an integrated circuit, such as a driver circuit, a logic circuit, an amplifier circuit, a control circuit, a demux-circuit, a modern circuit, and/or a transceiver circuit. Such an integrated circuit may also provide a low impedance to circuits of the constituent substrates of a substrate stack. Furthermore, a side substrate may be or comprise a circuit board, a printed circuit board (PCB), a ceramic substrate, and or a film carrier.

According to another embodiment of the present invention, a plurality of substrate stacks is formed by stacking entire wafers or parts thereof, and a subsequent cutting to provide the individual substrate stacks. According to another embodiment of the present invention, a plurality of substrate stacks is connected to an entire wafer, this wafer comprising a plurality of side substrates. After arranging the substrate stacks onto the side substrates, being still united on a wafer-level, and forming the respective solder connections, the wafer is cut in order to provide the individual integrated devices, comprising one substrate stack and at least one side substrate each. According to another embodiment of the present invention, the provision of the portions of the solder material on the side face of a substrate stack may be rendered obsolete and may be omitted. In such a case, portions of a solder material, such as a solder ball, a solder depot, or a solder coating of the respective contact pads of the side substrate may suffice and provide the material to form a solder connection. Possible alternatives to the solder connections may include a conductive adhesive, anisotropic conductive sheets, or mechanical electrical contacts.

According to yet another embodiment of the present invention, a plurality of substrate stacks is connected to one side substrate, which may then provide a circuit group, such as a memory module.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the scope of the invention, the scope of the invention being determined by the claims that follow.

What is claimed is:

1. An integrated circuit, comprising:
a substrate stack, comprising a first substrate and a second substrate being in a stacked arrangement with respect to one another; the substrate stack defining a top face, a bottom face and a side face; the first substrate comprising a first contact field on the side face of the substrate stack and the second substrate comprising a second contact field on the side face;
a side substrate, comprising a first contact pad and a second contact pad, the first contact pad being coupled to the second contact pad;
a first connection, connecting the first contact field and the first contact pad; and
a second connection, connecting the second contact field and the second contact pad.

2. The integrated circuit as claimed in claim 1, wherein the side substrate comprises a signal line connecting the first contact pad and the second contact pad.

3. The integrated circuit as claimed in claim 1, wherein the side substrate comprises a functional unit, the functional unit comprising any from the group of a capacitor, a resistor, a transistor, a diode, a signal line, a driver circuit, and an integrated circuit, and the first contact pad and the second contact pad being connected to the functional unit.

4. The integrated circuit as claimed in claim 1, wherein the first substrate comprises a first signal line extending toward the side face in an area of the first contact field and the wherein second substrate comprises a second signal line extending toward the side face in an area of the second contact field.

5. The integrated circuit as claimed in claim 4, wherein a cross-section of the first signal line comprises the first contact field and a cross-section of the second signal line comprises the second contact field.

6. The integrated circuit as claimed in claim 5, wherein the first signal line and the second signal line comprise respective bond wires.

7. The integrated circuit as claimed in claim 5, wherein the cross-sections of the first signal line and the second signal line are selected from the group of grinded, polished, cleaved, and cut signal lines.

8. The integrated circuit as claimed in claim 1, wherein the first substrate comprises a first integrated circuit and the second substrate comprises a second integrated circuit.

9. The integrated circuit as claimed in claim 1, wherein the side substrate comprises a third contact pad and a further signal line, the further signal line being connected to the third contact pad and the signal line.

10. The integrated circuit as claimed in claim 9, further comprising a solder ball arranged on the third contact pad.

11. The integrated circuit as claimed in claim 10, wherein the integrated circuit comprises a carrier substrate, the carrier substrate comprising a bond pad and a further contact pad, the bond pad being connected to the third contact pad of the side substrate and the further contact pad.

12. The integrated circuit as claimed in claim 11, further comprising a solder ball arranged on the further contact pad.

13. A memory device, comprising:
a chip stack defining a top face, a bottom face and a side face; the chip stack comprising a first memory chip and a second memory chip, the first memory chip comprising a first signal line and the second memory chip comprising a second signal line, the first signal line extending toward the side face of the chip stack in an area of a first contact field, and the second signal line extending toward the side face of the chip stack in an area of a second contact field;
a side substrate, comprising a first contact pad and a second contact pad, the first contact pad being coupled to the second contact pad;
a first connection, connecting the first signal line in the area of the first contact field to the first contact pad; and
a second connection, connecting the second signal line in the area of the second contact field to the second contact pad.

14. The memory device as claimed in claim 13, wherein the side substrate comprises a signal line connecting the first contact pad and the second contact pad.

15. The memory device as claimed in claim 13, wherein the side substrate comprises a functional unit selected from the group comprising a capacitor, a resistor, a transistor, a diode, a signal line, a driver circuit, and an integrated circuit, and the first contact pad and the second contact pad being connected to the functional unit.

16. The memory device as claimed in claim 13, wherein a cross-section of the first signal line comprises the first contact field and a cross-section of the second signal line comprises the second contact field.

17. The memory device as claimed in claim 16, wherein the first signal line and the second signal line comprise respective bond wires.

18. The memory device as claimed in claim 13, further comprising a carrier substrate, the side substrate with the chip stack being arranged on the carrier substrate, the side substrate comprising a third contact pad being connected to the signal line and the carrier substrate comprising a bond pad, the bond pad being connected to the third contact pad by a bond wire.

19. A circuit system comprising:
a substrate stack defining a top face, a bottom face and a side face; the substrate stack comprising a signal line extending toward the side face of the substrate stack and forming a contact field on the side face;
a side substrate, the side substrate comprising a first contact pad and a second contact pad, the first contact pad being coupled to the second contact pad;
a first connection, connecting the first contact pad to the signal line of the substrate stack via the contact field;
a circuit board, the circuit board comprising a third contact pad; and
a second connection, connecting the second contact pad to the third contact pad.

20. The circuit system as claimed in claim 19, wherein the side substrate comprises a signal line connecting the first contact pad and the second contact pad.

21. The circuit system as claimed in claim 19, wherein the side substrate comprises a functional unit, the functional unit comprising any from the group of a capacitor, a resistor, a transistor, a diode, a signal line, a driver circuit, and an integrated circuit, and the first contact pad and the second contact pad being connected to the functional unit.

22. The circuit system as claimed in claim 19, wherein the first contact pad is arranged on the top face of the side substrate and the second contact pad arranged on the bottom face of the side substrate, the bottom face of the side substrate facing a top face of the circuit board.

23. The circuit system as claimed in claim 19, wherein the first contact pad and the second contact pad are arranged on the top face of the side substrate; wherein the circuit board comprises an aperture, the substrate stack being arranged partly in the aperture; and wherein the third contact pad is arranged on a face of the circuit board facing the top face of the side substrate.

24. A circuit system, comprising:
a substrate stack, comprising a signal line extending toward a side face of the substrate stack in an area of a contact field;
a circuit board, the circuit board comprising a contact pad,
a connection, the connection connecting the contact pad to the signal line of the substrate stack in the area of the contact field;

25. A method of fabricating an integrated device, the method comprising:
providing a substrate stack defining a top face, a bottom face and a side face; the substrate stack comprising a substrate with a signal line, the signal line extending toward a side face of the substrate stack;
flattening the side face of the substrate stack, until a cross section of the signal line provides a contact field;
providing a side substrate comprising a contact pad;
arranging the substrate stack and the side substrate relative to one another such that the contact field faces the contact pad; and
connecting the contact field to the contact pad.

26. The method as claimed in claim 25, the method further comprising:
providing a solder material on the contact field of the substrate stack; and
wherein connecting comprises:
heating the solder material such that the solder material connects the contact field to the contact pad.

27. The method as claimed in claim 26, wherein providing the soldering material comprises providing a galvanic solution to the side face of the substrate stack.

28. The method as claimed in claim 25, the method further comprising:
providing a solder material on the contact pad of the side substrate; and
wherein providing of a connection, comprises:
heating the solder material such that the solder material connects the contact field to the contact pad.

29. The method as claimed in claim 25, wherein providing the substrate stack comprises:
bonding a bond wire to a bond pad, the bond pad being arranged on a substrate of the substrate stack; and
leading the bond wire at least to a position at which flattening of the substrate stack is performed.

30. The method as claimed in claim 25, wherein providing the substrate stack comprises providing an adhesive layer on a substrate of the substrate stack.

31. The method as claimed in claim 25, wherein flattening the substrate stack comprises a process selected from the group comprising: polishing, chemical mechanical polishing, cleaving, etching, grinding, sawing, machining, chipping and any combination thereof.
